(19) United States
(12) Patent Application Publication
(10) Pub. No.: US 2008/0257407 A1
(43) Pub. Date: Oct. 23, 2008

(54) Photoactive Devices and Components with Enhanced Efficiency

(75) Inventors: J. Wallace Parce, Palo Alto, CA (US); Calvin Y.H. Chow, Portola Valley, CA (US); Andreas P. Meisel, Redwood City, CA (US); Linh Nguyen, San Jose, CA (US); Erik C. Scher, San Francisco, CA (US); Jeffery A. Whiteford, Belmont, CA (US)

Correspondence Address: NANOSYS INC., 2625 HANOVER ST., PALO ALTO, CA, 94304, US

(73) Assignee: Nanosys, Inc., Palo Alto, CA (US)

(21) Appl. No.: 12/132,967

(22) Filed: Jun. 4, 2008

Related U.S. Application Data
(62) Division of application No. 11/271,484, filed on Nov. 10, 2005.
(60) Provisional application No. 60/629,095, filed on Nov. 17, 2004.

(51) Int. Cl. H01L 31/00

(52) U.S. Cl. 136/256

(57) ABSTRACT

Devices, compositions and methods for producing photoactive devices, systems and compositions that have improved conversion efficiencies relative to previously described devices, systems and compositions. This improved efficiency is generally obtained by one or both of improving the efficiency of light absorption into the photoactive component, and improving the efficiency of energy extraction from that active component.

### CROSS-REFERENCE TO RELATED APPLICATIONS

This application is a divisional of U.S. patent application Ser. No. 11/271,484, filed Nov. 10, 2005, which claims priority to U.S. Provisional Patent Application No. 60/629,095, filed Nov. 17, 2004, which is incorporated in its entirety herein.

### STATEMENT REGARDING FEDERALLY SPONSORED RESEARCH

Portions of this invention may have been made with United States Government support under National Reconnaissance Office Prime Contract No. NRO-000-01-C-0130. As such, the United States Government may have certain rights in the invention.

### BACKGROUND OF THE INVENTION

For photoactive devices and systems, the utility of the device or system is generally measured in terms of the efficiency with which it takes the ambient or incident light and converts that light to another form of energy, e.g., electricity, heat or light of different wavelength. The overall conversion efficiency is impacted by a number of factors for any given circumstance, including the amount of ambient light that impacts the photoactive components of the device or system, the amount of light that the photoactive components are able top absorb, the efficiency with which the active component converts absorbed light to such other form of energy, and the ability to extract or transfer that energy to a point at which it can be accessed and exploited. In photoactive devices, the losses at each of these steps substantially affect the overall efficiency of the device. It is the inefficiencies at these steps that can have some of the most substantial impacts on the conversions efficiency, and for example, are among the major stumbling blocks of cost effective solar energy, as the costs associated with producing more efficient devices, and their resulting yields, have not yet moved into the realm of cost effectiveness relative to other forms of energy production, e.g., fossil fuels.

Researchers have explored all aspects of the efficiency and cost equation in efforts to bring the cost of solar energy into line with the cost of other energy forms. For example, conventional photovoltaic cells made using rigid semiconductor substrates have been developed to the point where they are capable of converting greater than 30% of the incident light into electricity. However, the costs for achieving these efficiencies have proven too high for all but the most cost insensitive applications, e.g., space and military applications. At the other end of the equation, researchers have explored methods of producing solar cells from lower cost materials using high volume, low cost manufacturing techniques. For example, composite active layers have been explored that employ nano- or micro-crystal composites as a portion or all of the photoactive component of a photovoltaic device or system. These composites claim the benefit of potentially being processible like thin films or liquids to permit high volume, low cost application, using conventional technologies available in the film processing industries, e.g., roll-to-roll processing and lamination processing.

Such high volume manufacturing could substantially reduce the costs associated with photovoltaic device production relative to conventional semiconductor processes, provided the efficiency of the device is high enough.

While potentially dramatically reducing the costs of manufacturing of photovoltaic devices, these composite technologies have not yet achieved efficiencies necessary to provide a commercially viable approach to solar energy based electricity production. As a result, there exists a substantial need to provide low cost manufacturable photoactive devices with substantially improved conversion efficiencies. The present invention meets these and a variety of other needs by addressing many of the aforementioned inefficiencies.

The present invention generally provides devices, compositions and methods for producing photoactive devices, systems and compositions that have improved conversion efficiencies relative to previously described devices, systems and compositions. This improved efficiency is generally obtained by one or both of improving the efficiency of light absorption into the photoactive component, and improving the efficiency of energy extraction from that active component.

### BRIEF SUMMARY OF THE INVENTION

The present invention is directed to improved photoactive devices and components that make up such devices. In particular, the invention relates to improved compositions, architectures and processes whereby one can produce photoactive devices that more efficiently absorb the incident light for ultimate conversion to another energy form, e.g., electricity. Also included are improvements to device architecture that enhance extraction of converted energy from these photoactive devices, to further improve efficiency.

In a first aspect, the invention provides a photoactive device that comprises a photoactive layer sandwiched between the first electrode and a second translucent electrode, wherein the device is configured to provide an elongated light path length for light entering into the photoactive layer through the second transparent electrode. The elongated path length may be provided by providing multiple photoactive layers, or by redirecting or reflecting light back into a single photoactive layer.

In a related aspect, the invention provides a photoactive device that comprises a first transparent electrode, a photoactive composite layer, and a back electrode that has at least a first surface. The photoactive composite layer is deposited upon the first surface of the back electrode, and the transparent electrode layer is provided over the photoactive composite layer. In this aspect of the invention, the first surface of the back electrode comprises a reflective surface to reflect light back into the photoactive layer.

In an alternate aspect, the invention provides a photoactive device that comprises at least first and second discrete photoactive layers sandwiched between a first electrode layer and a second electrode layer. At least a first transparent boundary layer is provided that separates the first photoactive layer from the second photoactive layer, where the boundary layer is substantially discrete from each of the first and second photoactive layers.

In a related aspect, the invention provides a photoactive device that comprises first and second photoactive layers disposed between first and second electrodes, the first and second photoactive layers being separated by a recombination layer. The recombination layer typically comprises a conductive material and is configured to selectively and substantially conduct electrons from but not to the first photoactive layer to but not from the second photoactive sublayer.

Relatedly, the invention provides a photoactive device that comprises a back electrode layer, a transparent top electrode layer, and a plurality of discrete photoactive layers disposed between the back electrode layer and the top electrode layer, wherein each of the plurality of photoactive layers is separated from each other photoactive layer by a charge recombination layer comprised of a material that is different from the photoactive layers.

In addition to the foregoing, the invention also provides a photoactive device that comprises a first electrode layer, a photoactive layer disposed upon the first electrode layer, and a second electrode layer disposed upon the photoactive layer. The photoactive layer comprises at least a first sublayer comprising an electron donor material and substantially no electron acceptor material, a second sublayer disposed upon the first sublayer that comprises a mixture of electron donor material and electron acceptor material; and a third sublayer disposed upon the second sublayer that comprises an electron acceptor material and substantially no electron donor material. Typically at least one of the electron donor and acceptor materials comprises nanoparticles, e.g., nanorods, quantum dots, bucky balls, nanofibers or nanowires.

The invention also provides a transparent photoactive device, comprising first and second electrode layers that are transparent to at least a portion of a visible light spectrum, and a photoactive layer, wherein the photoactive layer comprises a population of nanocrystals as at least a portion of the photoactive layer, and further wherein the photoactive layer is transparent to a portion of a visible light spectrum. This aspect of the invention finds application in, for example, electronic devices with display or viewing windows, where the transparent photoactive device is disposed over the viewing window and is electrically coupled to the electronic device to provide electric power without impeding viewing through the viewing window.

The invention also provides processes for producing the foregoing photoactive devices. For example, in at least one aspect, the invention provides a method of providing a photoactive device that comprises providing a back electrode layer having a first surface, depositing a nanocrystal/first conductive polymer composite layer on the first surface, depositing a transparent electrode layer over the composite layer, wherein the transparent electrode layer comprises a second conductive polymer disposed in a nonaqueous solvent, and evaporating away the nonaqueous solvent to leave a transparent electrode layer.

### BRIEF DESCRIPTION OF THE DRAWINGS

FIG. 1 schematically illustrates a typical nanocomposite photoactive device.

FIG. 2 schematically illustrates light absorption issues in photoactive devices.

FIG. 3 schematically illustrates the redirection of light to enhance absorption in photoactive devices, in accordance with the invention.

FIG. 4A schematically illustrates a multilayered photoactive device of the invention. FIG. 4B illustrates a multilayered device that includes recombination layers. FIG. 4C shows an enlarged view of the operation of the photoactive layers separated by the recombination layers described herein.

FIG. 5 schematically illustrates a photoactive device that includes a photoactive layer that comprises multiple discrete sublayers.

FIG. 6 schematically illustrates a first embodiment of a multi-sublayer photoactive layer of the devices of the invention.

FIG. 7 shows an alternative embodiment of the multi-sublayered photoactive layers of the devices of the invention.

FIG. 8 shows another alternative embodiment of the multi-sublayered photoactive layers of the devices of the invention.

FIG. 9 shows a schematic illustration of the device architecture and electrode layout and connection of a prototype multilayered photoactive device of the invention.

### DETAILED DESCRIPTION OF THE INVENTION

### I. General Operation of Nanocomposite Photoactive Systems

Nanocomposite photoactive or photovoltaic devices have been previously described in the art. For example, Published U.S. Patent Application No. 20040118448 (incorporated herein by reference in its entirety for all purposes) describes photovoltaic devices that employ a nanocomposite active layer sandwiched between two electrode layers. The active layer includes semiconductor nanocrystals dispersed within a conductive polymer matrix. Together, the nanocrystals and polymer form a diode, where the nanocrystal and polymer posses a type-II energy band gap offset relative to each other. When the nanocrystals are exposed to light, an electron is displaced from its orbital within the nanocrystal, giving rise to an electron-hole pair, collectively referred to as an “exciton” within the nanocrystal. Typically, when the exciton is allowed to recombine within the nanocrystal, it results in a release of the stored energy, e.g., in the form of light. In the nanocomposite photoactive layer, however, the electron and its hole are separated from each other with the hole being conducted away from the nanocrystal by the conductive polymer and the electron being conducted away by the nanocrystal itself. The electron and hole are further extracted from the photoactive by virtue of the opposing electrodes between which the active layer is disposed or sandwiched, which conduct the different carriers depending upon their respective work functions.

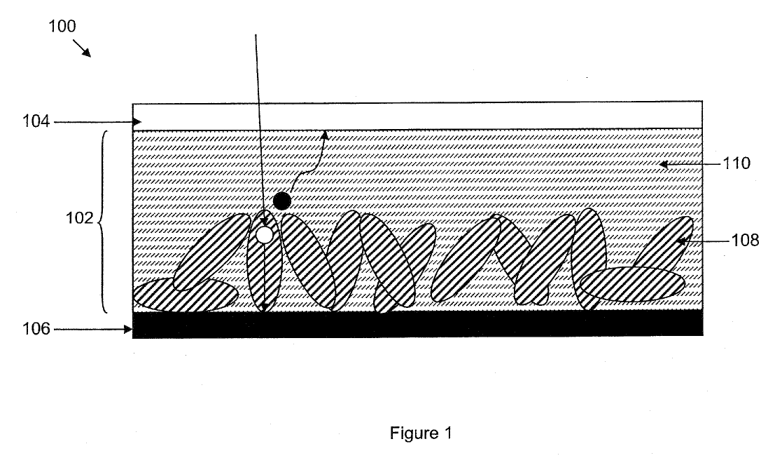

The general operation of a nanocomposite photoactive device as described above, is illustrated in FIG. 1. As shown and as noted above, a typical device 100 includes a photoactive layer 102 sandwiched between two electrode layers, 104 and 106. As shown, the photoactive layer 102 comprises a nanocrystal component 108 disposed within a surrounding matrix component 110. As shown, when light passes through a transparent electrode, e.g., electrode 104, into photoactive layer 102, it impacts and is absorbed by the nanocrystal component 108, resulting in displacement of an electron from its orbital to create an electron-hole pair, or “exciton” within the nanocrystal. Because of the energy bandgap offset between the nanocrystal and the surrounding matrix, the hole (as indicated by a black circle), is conducted into and through the matrix material 110 to electrode 104, while the electron (indicated by the white circle) is conducted through the nanocrystal 108 to the back electrode 106, to create the voltage potential across the photoactive layer.

Inefficiencies in the above architecture can arise in a number of areas, including when electrons and holes recombine before they are separated, where light is not completely absorbed by the photoactive layer, e.g., light passes through the active layer prior to impacting and being absorbed by a photoactive component, or where separated charges must travel through multiple hops or phases before traveling to the respective electrode.

### II. Improved Light Absorption

In at least a first respect, the present invention is aimed at improving the efficiency with which light is absorbed by a photoactive layer or an overall photoactive device, by increasing the probability that the light will be absorbed by a photoactive component, e.g., a nanocrystal. As a general matter, this is generally accomplished by configuring the device or components of such devices to increase the path length that light entering the photoactive layer will travel, and thereby enhance the probability that such light will be absorbed by the photoactive layer before it exits that layer or is absorbed by, e.g., a back electrode or surface or other non-photoactive component.

a. Redirection of Light to Improve Absorption

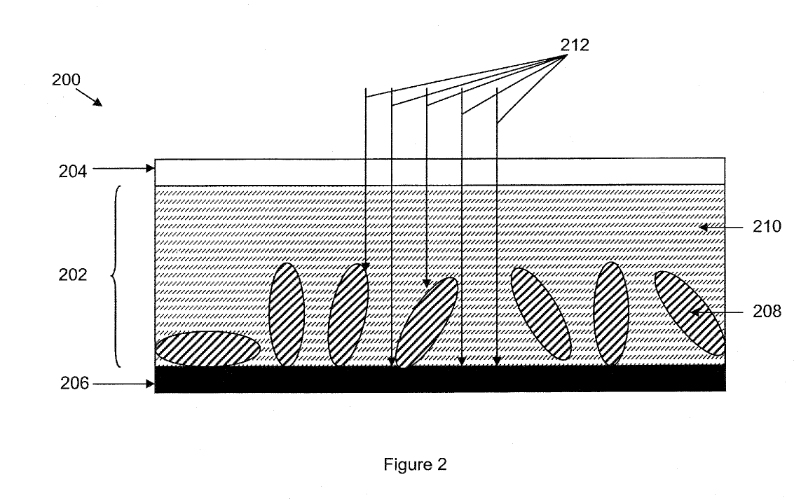

In a first aspect, the invention seeks to improve light absorption by redirecting light that passes through the active layer in order to increase the chance that the light will be absorbed by a photoactive component within the active layer. In particular, the present invention provides a reflective surface, and preferably a structured reflective surface upon the back electrode of the photoactive device so that light that passes completely through the active layer is reflected back into that layer for potential absorption by photoactive components. In preferred aspects, the light is reflected back orthogonally to the thickness dimension of the active layer, so as to provide a longer path along which it may be absorbed by a photoactive component, i.e., a photoactive nanocrystal. FIG. 2 schematically illustrates the issues sought to be addressed by this aspect of the invention. Briefly, a photoactive device 200 is comprised of a photoactive layer 202, sandwiched between two electrode layers 204 and 206, at least one of which, e.g., electrode layer 204, is transparent or substantially translucent. For ease of discussion, the photoactive layer 202 is illustrated as a composite of particles 208, e.g., nanocrystals, disposed in a matrix component 210, where the particulate component comprises the light absorbing, photoactive component. Light, indicated by arrows 212, passes through the transparent electrode 204 and into the photoactive layer 202. While some of the light is absorbed by the photoactive layer, some of the light may pass through that layer unabsorbed, and impact and be absorbed by the back electrode 206, impact another non-photoactive component (not shown), or where the back electrode 206 is transparent, pass out of the device unabsorbed. The unabsorbed light is thus lost from an efficiency standpoint.

While generally described in terms of nanocomposite photoactive layers that comprise a nanocrystal component and a conductive polymer component, e.g., a P3HT polymer, a number of the aspects of the invention, unless specifically required otherwise, may comprise a variety of different configurations of such photoactive layers, including, e.g., active layers that are just comprised of two different types of nanocrystals that possess a type-II energy band gap offset from each other, non-nanocrystal devices, e.g., that include only semiconductive polymers as the photoactive layer, and the like. Such compositions and architectures are generally described in Published U.S. Patent Application No. 20040118448, previously incorporated by reference herein.

In accordance with a first aspect of the invention, this unabsorbed light is sought to be absorbed by redirecting it through the photoactive layer to increase the likelihood that it will be absorbed. In particular, by reflecting the light back into the photoactive layer, one increases the chance that the light will impinge upon and be absorbed by a photoactive component. In merely reflecting the light directly back through the photoactive layer, one would expect to achieve absorption of approximately the same percentage of such light as was absorbed in the first pass. Specifically, if 50% of the light is absorbed on the first pass, approximately 50% of the reflected light should be absorbed on the second pass, for a total absorption of approximately 75% (allowing for losses in reflection, etc.). In order to ensure a higher percentage of absorption of the reflected light, the present invention not only reflects the unabsorbed light back into the photoactive layer, but directs such light at an angle that increases the reflected light's path-length through the photoactive layer so as to increase the likelihood of absorption before such light exits the photoactive layer.

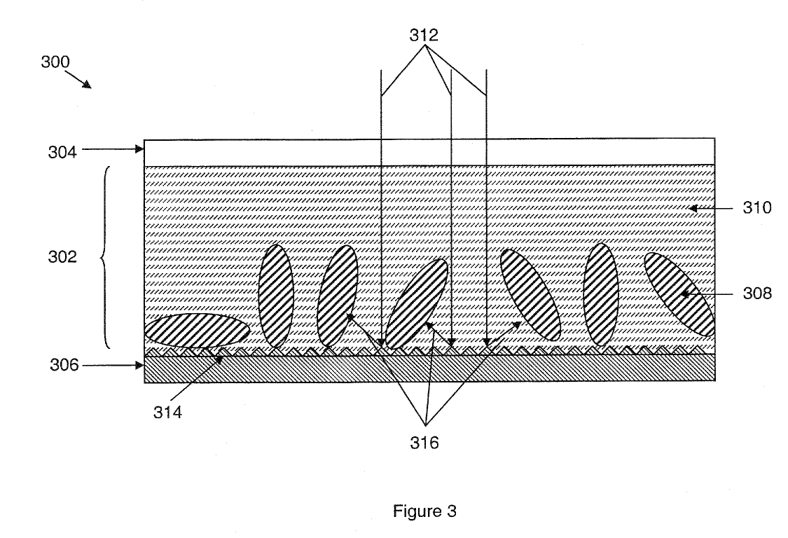

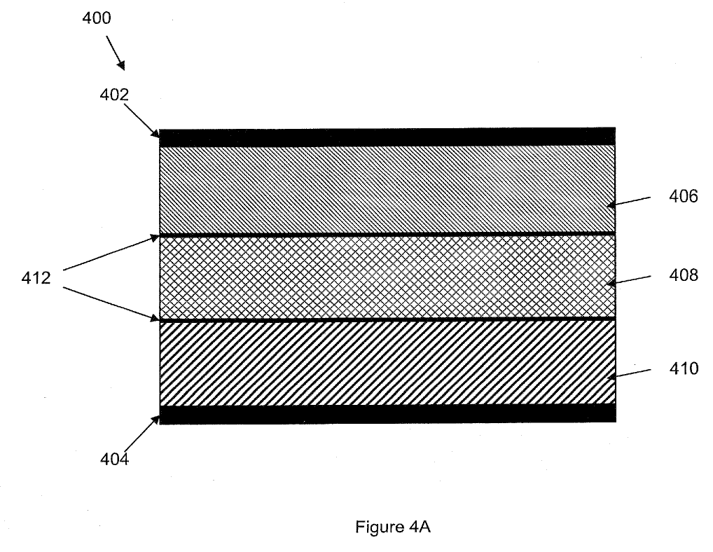

FIG. 3 schematically illustrates the redirection of unabsorbed light through the photoactive layer to achieve higher absorbance levels of light. For ease of discussion and illustration, the photoactive device 300 is shown with a nanocomposite photoactive layer 302 including nanocrystals 308 as the light absorbing component disposed in a conductive polymer matrix component 310, which together with the nanocrystal component possess the requisite type-II band gap offset. In particular, light, as indicated by arrows 312, passes through the photoactive layer 302 where some of the light is absorbed and some of the light is not. The unabsorbed light impinges upon the back electrode 306. Because the back electrode 306 includes a reflective surface 314, the unabsorbed light is reflected back into the photoactive layer 302. Further, because the reflective surface 314 of electrode 306 is structured, e.g., includes a prismatic or other contoured or structured surface, the light is reflected in directions that are not normal to the surface, e.g., as indicated by arrows 316. This redirection of unabsorbed light substantially increases the path length of the unabsorbed light through the photoactive layer 302 and increases the likelihood that such light will be absorbed.

Structuring of the reflective surface can generally take advantage of well known techniques that are used to enhance or redirect reflected light, e.g., as used in reflective surfaces, such as in signage, etc. For example, pyramid shaped or other prismatic surfaces or other structured surfaces are often employed to enhance reflection or redirect such reflection.

b. Multilayered Devices to Improve Absorption

In an alternative approach, a multiple photoactive layer device may be employed to increase the path length of relevant light entering into a given photoactive device, and thereby absorb light that is not absorbed in passing through a single photoactive layer. In particular, multiple photoactive layers are provided stacked upon each other, and separated by transparent electrode layers or charge recombination layers. Light that is not absorbed within the first photoactive layer passes through the separating layer and passes through a second photoactive layer, and optionally, a third, fourth, fifth or more layer.

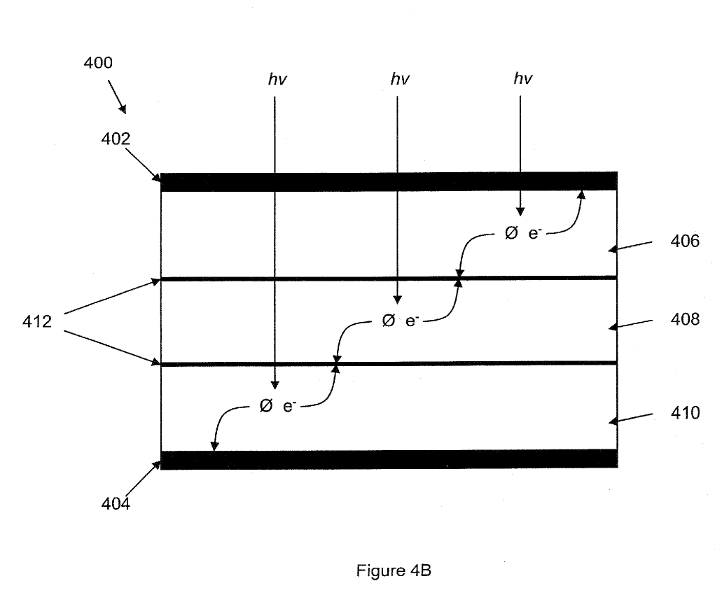

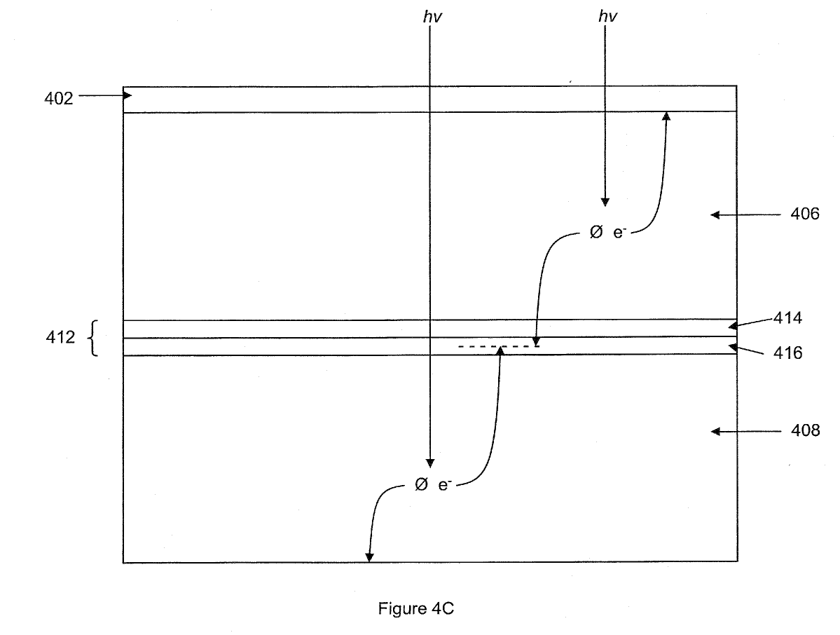

A schematic illustration of a multilayered photoactive device of the invention is shown in FIG. 4A. As shown, the device 400 again includes a top electrode 402 and a back electrode 404. In contrast to the devices shown in FIGS. 1-3, however, sandwiched between the top and back electrodes are multiple discrete photoactive layers 406, 408, and 410. For ease of illustration and description, FIG. 4 only shows a device having three discrete photoactive layers. However, as noted above, a device in accordance with this aspect of the invention may include from 2 to 10 or more photoactive layers, including, e.g., 3, 4, 5, 6, 7, 8, or 9 discrete photoactive layers.

As noted, each of the photoactive layers is discrete from its neighboring photoactive layer. By “discrete” in this context, is generally meant that each layer is structurally separated from the adjoining layer through a discernible structural boundary or boundary layer (shown in FIG. 4 as solid line 412). Typically, such boundary constitutes a different material type from the photoactive layers. For example, in at least one example, the boundary constitutes one or more intermediate transparent electrode layers that separate photoactive layers, e.g., thin conductive layers, such as Al, Ag, Au, Ca, Cr, Mg, LiF, TiO₂, or other metals that are transparent at low thickness, e.g., between 1 and 20 nm, or 1 and 10 nm. Likewise, other conductive materials, such as conductive organic materials, i.e., PEDOT, carbon based materials, i.e., carbon nanotubes or amorphous graphite, may be employed as the intermediate or recombination layer. In such instances, each photoactive layer with its associated electrode layers functions as a separate photoactive device, and is thus, electrically insulated from the adjoining photoactive device layer. In particular, each photoactive device layer can include a photoactive layer sandwiched by two electrodes, with an insulator disposed between two adjacent electrodes for two adjacent device layers. In such cases, in addition to being insulated from each other, each of the intermediate electrodes is separately electrically connected through the ultimate circuit, so that any electrical current generated within any given photoactive layer, is harnessed for use. Thus, each photoactive layer will include electrical leads connecting to its respective electrode layers. While this mechanism is useful for ensuring that one can absorb as much light as possible in a given area, it still can suffer from some of the cost and efficiency issues of a single layer device, e.g., inefficiencies associated with charge transport/conduction from the photoactive layer to the electrodes, etc., as well as cost issues associated with integration of electrode layers and connection thereto.

While described in terms of multiple layers to absorb optimal amounts of light, e.g., minimize light that passes through unabsorbed, it will be understood that the individual transparent device layers, e.g., not stacked into multiple layers, have substantial utility on their own. Specifically, a photoactive layer sandwiched between two transparent electrode layers may be applied on its own, e.g., in situations where light transmission is desired, but where electricity generation would also be of benefit. By way of example, such devices may be applied as layers of architectural glass, or as transparent power generators for use where there is limited space for a conventional, non-transparent photoactive cell. In such cases, one can exploit the photoactive cell as both a transparent barrier, e.g., a glass window, and exploit its power generation capabilities. Relatedly, one may use such transparent photoactive cells where a conventional cell would obscure the underlying component that is powered by that cell, or would otherwise add to the footprint of such a device. In particular, employing a transparent photocell over a visual display or viewing window would allow one to exploit the entire footprint of the display or viewing window for both power generation and viewing. Using conventional photocells, one would require a greater footprint size and would be required to place the photocell adjacent to the viewing area, thus increasing the overall footprint of the device. In a number of cases, this would be particularly preferred for low power display applications, e.g., shelf signage in stores, e.g., supermarkets, that employ small LCD displays, calculators, watches, clocks, handheld computer games, and the like. Likewise, such uses are directly related to architectural glass applications of the photoactive devices of the invention, where the entire surface of a window may also be employed in solar energy conversion. While the inability of the overall device/window may not provide optimal amounts of power generation, e.g., enough power to meet all needs of the building, due to its inability to absorb all incident light, the incremental power generation that was previously wasted provides significant advantages in energy efficient building design.

The transparent photoactive devices described above are generally electrically coupled to the underlying electronic device, or in the case of architectural glass, to a power conversion and storage facility within the building or directly connected to the window or glass component. In the case of electronic devices, and particularly those having electronic displays, the photoactive device is generally electrically connected to the device so as to provide electricity to the underlying display. Such connection may be direct, e.g., through appropriate circuitry connecting it to the display and/or the entire device that the display is applied to, e.g., a calculator, etc., or it may be indirectly connected, e.g., being connected to a battery which stores converted energy for later or unvarying supply of electricity. In either case, such photoactive devices are referred to as being electrically connected to the display.

In the foregoing photoactive devices, it will be appreciated that a substantial amount of light transmission is tolerated, and even desired, so that one can view the underlying display, or see through the window. Titration of the amount or wavelength of passed or transmitted light may depend upon the particular application, the type of light that is sought to be absorbed for the given device, e.g., the predominant light source, etc. In any event, the nanocrystal composites described herein are readily tuned to adjust their absorption spectra by adjusting the size and/or composition of the nanocrystal component of the composite.

In an alternative architecture, the boundary layer may comprise a layer of material that operates as a charge recombination layer for charges separated from the various photoactive layers, but that does not require any electrical connectors, e.g., pin-outs, attached to such intermediate layers. While referred to as a charge recombination layer, such terminology is primarily used to describe an intermediate or middle electrode layer (and both terms may be used interchangeably with the phrase “recombination layer”) that is not separately connected to the external circuit. While it is believed that this layer operates as a layer where charges recombine, the use of the term “recombination layer” should not be construed as binding the presently described invention to any particular theory of operation, and is primarily used for ease of discussion subject to the foregoing. In particular, stacking photoactive layers together, separated by a charge recombination layer, effectively functions in the same manner as batteries arrayed in series, such that it generates effectively the same current level as a single layer but at a higher voltage, thus providing higher power per unit area of photoactive device footprint.

FIG. 4B schematically illustrates a photoactive device 400 having charge recombination layers 412 between the discrete photoactive sublayers 406, 408 and 410. In particular, as shown, device 400 includes photoactive sublayers 406, 408 and 410, separated by boundary layers 412. Each of photoactive sublayers 406, 408 and 410 may be comprised of the same or different materials, and such materials are typically as recited elsewhere herein for photoactive layer compositions, e.g., in preferred aspects comprising a nanocrystal component as at least one portion of the photoactive layer. When light, indicated by the arrows, enters into the first photoactive layer 406, e.g., through a transparent top electrode, such as electrode 402. Some of the light is absorbed by the first photoactive sublayer 406, while the unabsorbed light passes into the underlying photoactive layers 408 and potentially 410, where more of the incident light is absorbed by these photoactive sublayers, and generates electron-hole pairs (shown by Ø for holes and e- for electrons).

As noted, in this particular aspect, boundary layers 412 comprise a charge recombination layer, e.g., a layer that receives electrons from one photoactive layer and holes from the other, and allows them to recombine. As noted, charge recombination layers are typically configured to selectively accept electrons from one photoactive layer and holes from the other photoactive layer adjoining that recombination layer. As such, recombination layer may be comprised of a variety of different materials, including, e.g., metal layers, i.e., gold, platinum, aluminum, indium-tin-oxide (ITO), etc. or may alternatively be comprised of conductive or semiconductive organic materials, e.g., polymers, carbon based materials, e.g., nanotubes, amorphous graphite, and the like. In many cases, a recombination layer may be comprised of more than one type of material layer. For example, a recombination layer typically includes a highly conductive material, but may also include a blocking layer to selectively block one charge carrier from one of the adjoining photoactive layers. As noted previously, these recombination layers are preferably transparent to allow light not absorbed by one layer top pass to the next layer. As such, in many cases, e.g., in the case of metals or other materials that are not generally transparent in a thicker bulk state, such layers may be provided at thin enough dimensions to remain transparent and/or translucent. Typically, such thin metal coatings are as used in glass coating processes for, e.g., architectural glass.

In operation, electron-hole pairs generated within each photoactive layer (shown by Ø for holes and e- for electrons) are separated within each of the discrete photoactive layers. Electrons are selectively conducted toward one recombination layer while holes are conducted to the other (by virtue of an included blocking layer and an increase in electrons in that particular recombination layer that further attracts holes to the recombination layer). Although referred to herein differently as electrons and holes, it will be understood that such designation generally refers to a directional flow of electrons, e.g., if holes are “conducted from node A to node B, it is the same as electrons being conducted from node B to node A. Likewise, in describing material as a hole conductor, it will be appreciated that such material is also termed an electron donor material, while electron conductors, as used herein, are also termed electron acceptor materials. Electrons and holes recombine within the recombination layer, while some are conducted to the electrodes to generate current, but at a higher voltage than with a single layer.

FIG. 4C shows an enlarged view of the operation of the photoactive layers separated by the recombination layers described herein. As shown, the upper photoactive layer 406 is bounded on top by transparent electrode 402. Separating photoactive layer 406 from photoactive layer 408 is boundary layer 412. As described above, boundary layer 412 comprises a charge recombination layer 416 and a blocking layer 414. When light impinges upon the photoactive layer 408, it generates an electron-hole pair. As shown, the work function of the recombination layer 416 is such that it favorably conducts electrons out of the photoactive layer 408, building up a negative charge within the recombination layer 416 (as shown by the “- - - ” within the layer). Concurrently, electrons separated from their holes in photoactive layer are blocked form being conducted into recombination layer 416 by the inclusion of blocking layer 414. Because of the blocking layer, the relative negative charge within recombination layer 416, and the work function of electrode 402 that favors electron conduction from the photoactive layer 406, the holes are selectively conducted through the blocking layer 414 into recombination layer 416, where they recombine with the electrons from the lower layer. In the meantime, electrons in photoactive layer 406 are conducted into electrode 402 while holes in photoactive layer 408 are conducted to the next layer down (not shown), but which could be another recombination layer (or layers) as shown in FIG. 4B, or the bottom or back electrode, e.g., electrode 404 in FIG. 4B, which is selected to have a work function that favors hole conduction.

The various active layers may be comprised of different photoactive components in some cases, whereas in other cases, they may be comprised of the same materials. For example, where one wishes to tailor each layer to absorb different portions of the light spectrum that is incident upon the overall device, one may use materials in each layer that absorb at different wavelengths, thus allowing one to capture a broader portion of the spectrum. Alternatively, where one simply wishes to absorb the same wavelength of light in each layer, but capture more of that light, e.g., that which passes through a preceding layer, then the active photoactive layer components may be uniform among the different layers. Additionally, even where the component materials of different photoactive layers are the same, such layers may differ in their thickness, in their relative concentrations of, e.g., nanocrystal and polymer, and in their electrode make-up. For example, a variety of combinations of electrode metals or other materials, e.g., Al, Ag, Mg, Ca, Au, PEDOT, carbon materials, etc, may be provided in various combinations either between electrodes in a single device, or as an alloy or composite within a given electrode, and such materials may be varied across a multilayered device.

As noted above, the recombination layer is maintained as a discrete layer from the photoactive layers that it bounds. As a result, fabrication of a device including such layers requires the ability to mate discrete layers of different materials together. Such methods may involve lamination processes where different layers exist separately as films that are subsequently laminated together. While potentially useful, the requirements of intimate contact between layers may place a high burden upon such a lamination process. Alternatively, the recombination layer is deposited upon the underlying layer in a solution or otherwise fluid form or using a vapor or gas phase deposition technique. For example, in the case of metal recombination layers, such material may generally be evaporated onto the underlying layer or sputtered onto that underlying layer using well known techniques.

Where recombination layers are comprised of more than one sublayer, e.g., including a blocking layer, it may be that such other layer is deposited upon the first, photoactive layer by a film deposition method similar to that used to deposit the underlying layer, e.g., spin or tape casting methods, screen printing or spreading methods, e.g., using a doctor blade, etc. In many such cases, it is desirable to provide the additional layer without permitting intermixing with the underlying photoactive layer. As such, it may be necessary to provide the second layer in a solvent or matrix that prohibits any excessive resolubilization of or intermixing with the first layer, as well as preventing any other degradation of that underlying layer, e.g., by exposure to harmful solvents such as water, or exposure to oxygen, or the like. In at least a first example, a blocking layer is deposited over a photoactive layer, either as a portion of a recombination or other boundary layer, or as a layer adjacent to an electrode of the device. In depositing this blocking layer, it will be desirable to minimize resolubilization of the underlying active layer.

Additionally, it will be desirable to avoid exposing the underlying photoactive layer to any adverse conditions associated with deposition of the blocking layer material. For example, many conductive polymers, e.g., that are used as matrices for photoactive nanocomposites, are oxygen and/or water sensitive. As such, depositing a water based material or working in an oxygen rich environment can damage the underlying photoactive layer. Previously described blocking layers have used a conductive polymer, poly(3,4-ethylenedioxythiophene) doped with poly(styrenesulfonate) (“PEDOT-PSS”). Typically, such PEDOT-PSS has only been solubilized in aqueous solutions which could not be prepared or used in the oxygen-free and water-free environments often required for manipulation of the photoactive composites. In particular, contamination of water or oxygen sensitive materials, e.g., the photoactive nanocrystal/P3HT blends. Accordingly, the present invention takes advantage of a discovered ability to solubilize such organic conductive polymers in organic solvents, and particularly, alcohols, such as ethanol and methanol. In addition to being manipulable in water-free and oxygen-free environments, such alcohol-based solutions also benefit from reduced resolubilization of the underlying photoactive layer, as that layer is insoluble in the alcohol.

### III. Heterostructured Active Layers

As noted previously, another method of improving the overall efficiency of photoactive devices of the invention, is to improve the efficiency with which charges are separated within and extracted from the photoactive layer. In particular, charge separation may be enhanced by providing an increased interface region between an electron donor and electron acceptor so as to prevent charge recombination within one or the other. Additionally, once the charges are separated, efficiencies could be improved by providing as direct a path as possible for a given carrier to its electrode while not permitting it to shunt to the other electrode or contact the other charge carrier in transit. The present invention addresses this by providing a photoactive layer that includes at least three sublayers: an electron donor layer, an electron acceptor layer, and a graded or mixed layer between the two.

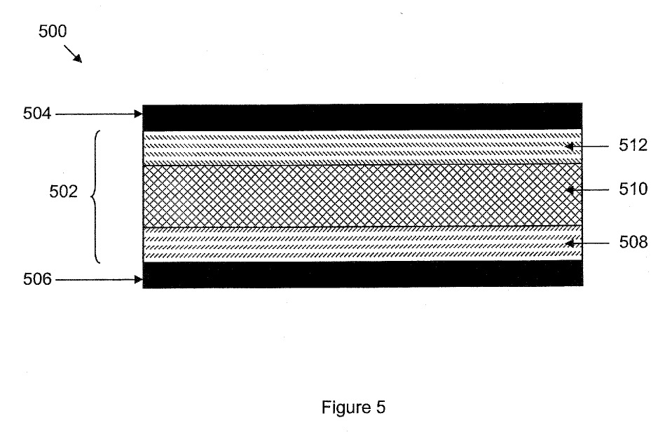

FIG. 5 schematically illustrates a photoactive device 500 that includes a three sublayer architecture of the photoactive devices of the invention. Briefly, the device includes two opposing electrode layers 504 and 506 that sandwich between them the overall photoactive layer 502. The photoactive layer 502 is, itself comprised of three sublayers, 508, 510 and 512, respectively. The first sublayer 508 generally comprises an electron donor material but includes substantially no electron acceptor material, so as to avoid any charge shunting to electrode 506. The second sublayer 510 is a mixture of electron donor material and electron acceptor material, and the third sublayer 512 comprises the electron acceptor material, but includes substantially no electron donor material.

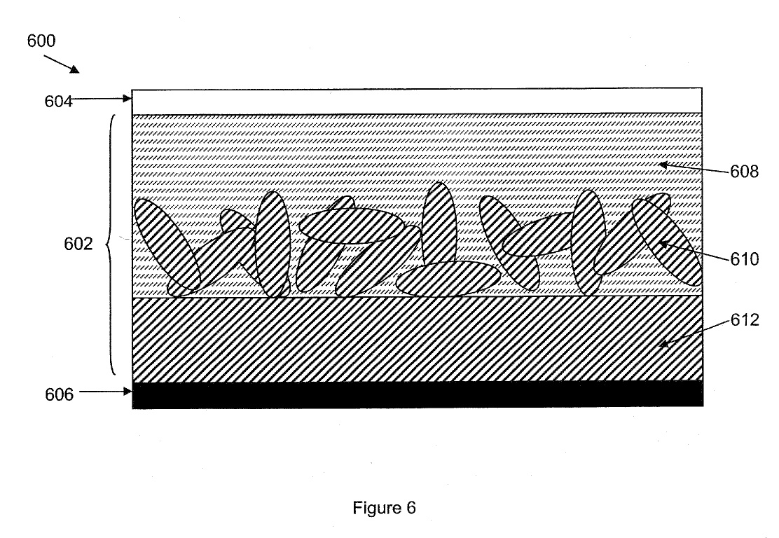

Generally, at least one of the three sublayers will comprise a nanocrystal component. Further, in most aspects, at least one of the three sublayers will comprise a transparent material to allow for light absorption within the photoactive layer. In many aspects, one of the electron donor or acceptor material layers, e.g., the first and third sublayers, will comprise a bulk material. As used herein, a bulk material refers to a solid, monocrystalline, polycrystalline, or amorphous substrate that is usually nonporous. A variety of different architectures that fits these criteria may be used. A few of these are schematically illustrated in FIGS. 6-8.

In a first aspect, FIG. 6 illustrates a device 600 that includes top electrode 604 and back electrode 606, that have sandwiched between them the photoactive layer 602. Photoactive layer 602 comprises three discrete sublayers 608, 610 and 612. As shown, sublayer 612 comprises a bulk electron acceptor material. Intermediate sublayer 610 comprises a mixed layer of electron acceptor material, shown as nanocrystals 614, and electron donor material shown as conductive polymer 616. Finally, sublayer 608 is shown as comprised entirely of conductive polymer 616. In operation, light impinges upon the nanocrystal component 614 in sublayer 610 to form an exciton which is then separated into the bulk electron acceptor and electron donor polymer component in the overall photoactive layer. Because these additional sublayers are provided, they reduce the probability that there will be any charge recombination within the photoactive layer of the device.

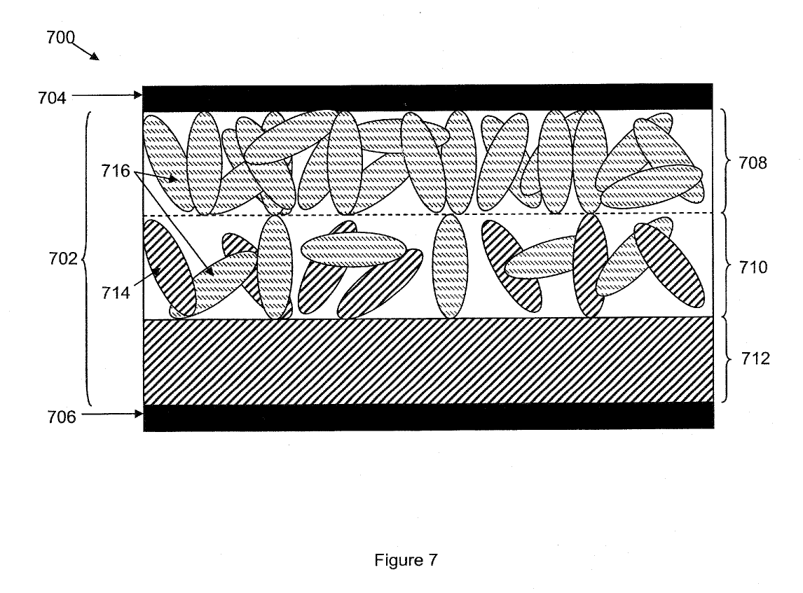

An alternate arrangement/architecture of a multi-sublayered photoactive layer is illustrated in FIG. 7. As shown, the photoactive device 700, again includes a photoactive layer 706 sandwiched between a top and back electrode 702 and 704, respectively. The photoactive layer 706 again includes three discrete sublayers 708, 710 and 712, with sublayer 712 comprising an electron acceptor material and substantially no electron donor material, sublayer 708 comprising electron donor material and substantially no electron acceptor material, and the intermediate sublayer 710 comprising a mixture of electron donor and acceptor material. As shown in FIG. 7, however, while sublayer 712 again comprises a bulk electron acceptor material, sublayer 708 comprises a nanocrystal based electron donor material, e.g., as shown by nanocrystals 716. As such, the intermediate sublayer 710 is comprised of a mixture of electron acceptor nanocrystals (714) and electron donor nanocrystals (716).

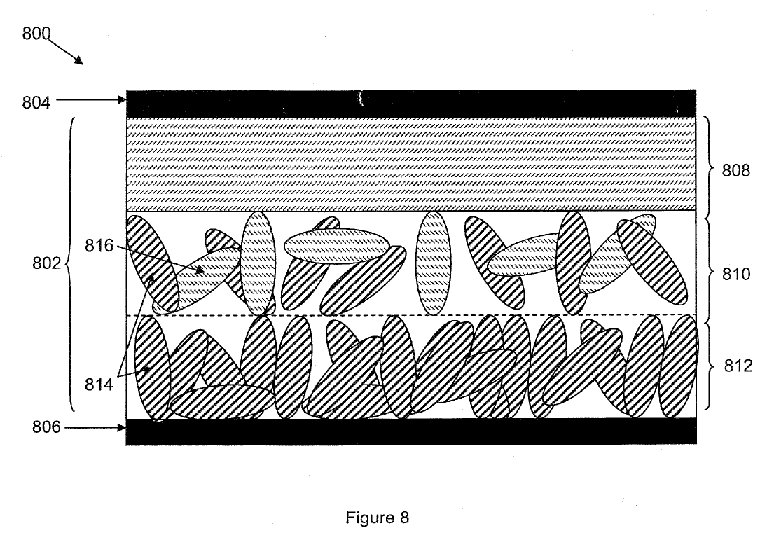

Still another variation of the devices of the invention is illustrated in FIG. 8. As with the prior examples, the overall photoactive device 800 includes a multilayered photoactive layer that is comprised of three sublayers, 808, 810 and 812, where sublayer 812 comprises electron acceptor material but substantially no electron donor material, sublayer 810 comprises a mixture of electron donor material and electron acceptor material and sublayer 808 comprises electron donor material but substantially no electron acceptor material. As shown ion FIG. 8, however, sublayer 812 comprises an electron acceptor material that comprises nanocrystals (814). Likewise, both the electron acceptor and electron donor components of the intermediate sublayer 810 comprise nanocrystals, e.g., nanocrystals 814 and 816, respectively. Sublayer 808, on the other hand, comprises an electron donor polymer materials and substantially no electron acceptor material.

As will be clear upon reading this disclosure, in preferred aspects of the invention, the intermediate sublayer will generally comprise nanocrystals as at least one of the electron donor or acceptor material, and in some cases both the electron donor and electron acceptor components. As such, the material in the layers adjacent to the electrodes will generally be selected from a semiconducting polymer, a nanocrystal material and/or a bulk material.

### IV. Examples

A. PEDOT from Ethanol/Methanol:

Devices incorporating PEDOT-PSS spun from ETHANOL yielded efficiencies of 3.0% and showed similar performance to regular PEDOT. Similar results have been achieved for devices with PEDOT-PSS spun from METHANOL (3.1%). The latter even exceeded the performance of regular devices (but it is not clear whether this was due to differences in PEDOT only—I would just claim that they are comparable, but not PEDOT spun from Methanol yields better performance).

B. Multilayer Devices

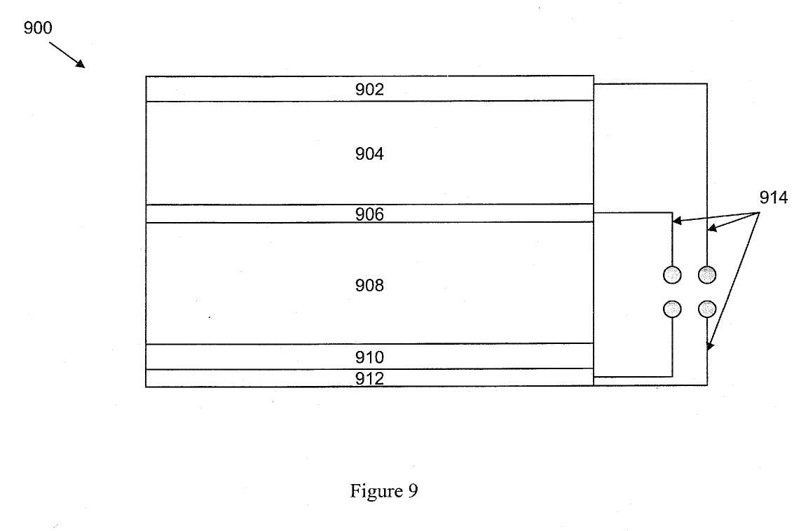

Multilayer devices have been fabricated, comprising two photoactive layers made of CdSe nanocrystal-P3HT blends. The first blend layer (˜40 to 60 nm thick) was deposited onto a transparent ITO/PEDOT substrate and covered with a transparent Al (8 to 12 nm) electrode and in some cases, an additional PEDOT layer, which was spun from Methanol (30 nm thick). A second blend layer (˜60 to 90 nm thick) was spun on top and covered with a 130 nm thick Al electrode. An electrode pattern was designed for the devices that allowed for independent pin-out of the respective electrodes, i.e. pin-out of the bottom cell only, the top cell only, and/or the entire cell. By this, independent measurement and understanding of the contributions of the respective layers was possible. FIG. 9 shows a schematic of the device architecture used for the multilayer cell. As shown, the device includes separate pinouts for each electrode layer, e.g., the top, middle and bottom electrodes. As illustrated, the device 900 included a top electrode layer 902, a top photoactive layer 904, a middle electrode layer 906, a bottom active layer 908, a PEDOT blocking layer 910, and a transparent bottom electrode layer 912 of ITO. Also as shown, each of the three electrode layers included separate pinout connections 914 for ascertaining the current derived from each photoactive layer. As noted above, each layer contributed to the overall electric conversion efficiency of the device 900.

Devices have been fabricated, and they did show good performance, probably in the region of 2 to 3%, but so far, we cannot give accurate numbers, due to uncertainties in the actual device areas.

Although described in terms of nanocrystal components and bulk components, it will also be appreciated that an entirely polymer based system may be employed as well, e.g., with electron acceptor polymer layers and electron donor polymer layers separated by a mixed polymer layer. Similarly, while described in certain orientations in terms of whether the bulk or crystal layers are electron acceptor or electron donor materials, it will be clear to those of skill in the art that either the acceptor or donor material may exist as a bulk material, a nanocrystal material, a polymer material, or a composite of these.

What is claimed:

1. A photoactive device, comprising:
a first electrode layer, a photoactive layer disposed upon the first electrode layer, and a second electrode layer disposed upon the photoactive layer; and
wherein the photoactive layer comprises first sublayer comprising an electron donor material and substantially no electron acceptor material, a second sublayer disposed upon the first sublayer that comprises a mixture of electron donor material and electron acceptor material; and a third sublayer disposed upon the second sublayer that comprises an electron acceptor material and substantially no electron donor material.

2. The photoactive device of claim 1, wherein at least one of the electron donor material and electron acceptor material comprises a first population of nanocrystals.

3. The photoactive device of claim 1, wherein at least one of the first sublayer comprises a bulk electron donor material.

4. The photoactive device of claim 1, wherein the third sublayer comprises a bulk electron acceptor material.

5. The photoactive device of claim 4, wherein at least one of the first sublayer, second sublayer and third sublayer are treated to prevent intermixing of the first, second and third sublayers.

6. The photoactive device of claim 4, wherein the at least one sublayer comprises nanocrystals, and is annealed to prevent intermixing with other sublayers.

7. The photoactive device of claim 6, w herein the at least one sublayer comprises polymer, and is cured to prevent intermixing with other sublayers.

8. The photoactive device of claim 1, wherein at least one of the electron donor material and electron acceptor material comprise a conductive polymer.

9. The photoactive device of claim 1, wherein the electron donor material comprises a first population of nanocrystals and the electron acceptor material comprises a second population of nanocrystals, wherein the first and second populations of nanocrystals possess a type-II energy band gap offset relative to each other.

10. The photoactive device of claim 1, wherein the electron donor material comprises a first population of nanocrystals and the electron acceptor material comprises a first conductive polymer, wherein the first population of nanocrystals and the first conductive polymer possess a type-II energy band gap offset relative to each other.

11. The photoactive device of claim 1, wherein the electron donor material comprises a first conductive polymer and the electron acceptor material comprises a first population of nanocrystals, wherein the first population of nanocrystals and the first conductive polymer possess a type-II energy band gap offset relative to each other.

12. The photoactive device of claim 1, wherein the electron donor material comprises a first conductive polymer and the electron acceptor material comprises a second conductive polymer, wherein the first conductive polymer and the second conductive polymer possess a type-II energy band gap offset relative to each other.
